(19) United States
(12) Patent Application Publication
(10) Pub. No.: US 2001/0010393 A1
(43) Pub. Date: Aug. 2, 2001

(54) Semiconductor device and semiconductor device mounting method thereof

(75) Inventor: Tomoo Murakami, Tokyo (JP)

Correspondence Address: HELFGOTT & KARAS P.C., 6th Floor, Empire State Building, New York, NY, 10118-0110, US

(73) Assignee: NEC CORPORATION

(21) Appl. No.: 09/737,658

(22) Filed: Dec. 15, 2000

(30) Foreign Application Priority Data
Dec. 17, 1999 (JP) 359165/1999

(51) Int. Cl. H01L 21/44; H01L 23/06; H01L 23/48; H01L 23/52; H01L 29/40

(52) U.S. Cl. 257/684; 438/612; 438/615; 257/737

(57) ABSTRACT

On an inner side of a mounting pad on a circuit substrate, a plurality of solder resist zones are disposed to project from the substrate. Sealing resin is applied by one-point coating onto a central position of the solder resist zones. A semiconductor device is place on the substrate. While heating the resin under pressure, the semiconductor device is mounted on the substrate. Therefore, the sealing resin is supplied to each vertices of the projecting solder resist zones disposed in circumferential areas on the substrate, and hence a filet is uniformly formed on the substrate. In the LSI semiconductor device mounting process using pressure welding, highly reliable connection can be achieved by one-point coating using a dispenser at a low cost with high productivity.

### BACKGROUND OF THE INVENTION

The present invention relates to a semiconductor device and a semiconductor device mounting method of packaging or mounting a semiconductor device including a plurality of projected electrodes on a substrate including a mounting pad thereon.

### PRIOR ART

To package or to mount a bare chip on a substrate, a pressure welding method has been broadly employed. In the pressure welding, it is not necessary to supply bonding material such as solder or conductive resin as described in Japanese Patent Publication No. 2770821. Electrodes of a semiconductor device of large scale integration (LSI) is electrically connected to a pad on a substrate only by mechanical contact using force of contraction of sealing resin filled between the semiconductor device and the substrate.

In this manufacturing process, sealing resin is supplied onto an area of the substrate on which an LSI semiconductor device is to be mounted or packaged. The semiconductor device is mounted on the sealing resin. The sealing resin is cured or hardened by heat and high pressure to contact the electrodes to each other. In the pressure welding, sealing resin beforehand supplied on the substrate is expanded by the LSI semiconductor device and is filled in a gap between the semiconductor device and the substrate. However, it is difficult to form, by expanding the resin, a filet in a circumferential area of the semiconductor device, the filet being uniform in quantity of resin. The filet has a contour strongly influenced from a resin supplying method.

In known resin supply methods, a resin dispenser is employed or a photographic technique is utilized. When a dispenser is used, resin is supplied by one-point coating, multi-point coating, or multi-point nozzle coating. The one-point coating has been most generally used to supply resin. Specifically, a required quantity of resin is supplied onto one point in a central section of the packaging or mounting area. When compared with other methods employing a dispenser, this method is relatively less expensive and has a high operation speed.

However, when resin having high viscosity or resin having a high curing speed is adopted, for example, the former thermo-set resin is cured 1 min. or more at 200° C., and high curing resin used in the present invention is cured ½ min or less, and curing or setting the contour of resin applied onto the substrate is expanded without changing the contour and is cured in the contour thus expanded. In the ordinary one-point coating by a dispenser, resin supplied onto the substrate is kept in a semispherical contour by surface tension on the substrate. When the resin is expanded by an LSI semiconductor device having a rectangular form, the resin is expanded in a circular shape. As a result of the expansion, a filet is formed in a contour which is insufficient at corner areas of the LSI semiconductor device.

Specifically, FIGS. 1 to 3 show representative solder resist patterns in the semiconductor device packaging process when an LSI semiconductor device is mounted on a substrate in the prior art. In the solder resist patterns of the prior art, no item hinders a flow of resin supplied onto the substrate in the semiconductor device packaging process. When the one-point coating is employed to supply resin, the resin supplied has a semispherical contour on the substrate. As the semiconductor device descends, the supplied resin on the substrate is expanded in a circular contour. The expanded resin is insufficient in the packaged item at the corner sections or areas of the semiconductor device. The sealing resin used in the present invention reduces volume when it is cured. Therefore, bump electrodes of LSI and mounting pad of the substrate are contacted closely and conducting between circuit-board and LSI are performed perfectly. When as before-mentioned, corner area of LSI is insufficient, or there is void in the corner area, there has unconducting part between bump electrodes of LSI and mounting pad of the substrate or, even if mounting semiconductor device is conducted, then, it may missed conductivity between them after elapsed time.

To overcome this difficulty, Japanese Patent Application Laid-Open No. HEI 11-307584 entitled “A Semiconductor Device Manufacturing Method” describes a process in which after stepwise lowing temperature of the heating process on the LSI semiconductor device down to a relatively low temperature range (about 100° C.), the temperature is kept unchanged for a while to decrease viscosity of the resin. The resin is uniformly expanded by the LSI semiconductor device in this state and is then heated again to be cured. By using this process, the filet having a uniform quantity of resin can be fabricated in the circumferential area of the LSI semiconductor device.

However, when resin which is set in a short period of time is employed to increase productivity, it is difficult to guarantee a stage in which the resin is expanded by the LSI semiconductor device in a wet state. This adversely influences a contour of the filet thus produced. Particularly, using the one-point coating, the resin is insufficient at the corner areas of the semiconductor device. In this situation, the resin is expanded in a circular contour by a rectangular LSI semiconductor device. Consequently, if a sufficient quantity of resin is to be supplied to the corner areas, the total amount of resin must be increased. Considerably a large volume of filet is required at each corner area. Interference possibly occurs between adjacent ones of such filets in a case of a multi-chip module (MCM).

To improve the drawback, not using one-point coating but a resin supply method called “multi-point coating” has been proposed. In the multi-point coating, resin is beforehand supplied to areas in which it is considered that resin becomes insufficient when expanded by a semiconductor device. The multi-point coating method solves the problem of the one-point coating, namely, insufficient resin in the corner areas, and the contour of the filet is improved. However, since the one-point coating is repeatedly executed in the multi-point coating, the resin supply time is elongated and the overall productivity is lowered.

On the other hand, the multi-point nozzle coating process employs a nozzle including a resin ejecting hole for each position of a point at which the resin is supplied. That is, only one resin supply operation is required in the process and hence the overall productivity is not decreased. However, the multi-point nozzle must be prepared depending on the shape of each LSI semiconductor device. Moreover, the multi-point nozzle is expensive. So, higher cost is required by using the multi-point nozzle coating.

Known as a secondary resin supply method is also a printing method in which a required quantity of resin is printed on positions at which an LSI semiconductor device is mounted. In the printing method, resin can be supplied according to a contour of the LSI semiconductor device. This method also prevents the drawback in which the resin is expanded in a circular contour as in the one-point coating. However, the resin supply process must be accomplished before the mounting process. Therefore, resin having a short pot life is not suitable for the process. Additionally, in the packaging process, the substrate is heated in many cases to prevent heat from being imparted from the semiconductor device to the substrate side. Disadvantageously, heat of the substrate may possibly proceed hardening of the supplied resin.

Although the one-point coating by a dispenser is advantageous to supply resin in consideration of the manufacturing cost, productivity and sufficient conductivity of packaging, the filet formation is attended with the problems.

### SUMMARY OF THE INVENTION

It is therefore an object of the present invention to provide a semiconductor device characterized in that;

having a plural of solder resist between a pair of mounting pad line set up nearly parallel to said mounting pad line each other;

said solder resist constructing up to a corner portion of said mounting pad lines so as to spread a sealing resin uniformity when said semiconductor device is set on said mounting pad.

In accordance with the present invention, there is provided a semiconductor device characterized in that;

having a plural of solder resist between a pair of mounting pad line set up nearly parallel to said mounting pad line each other;

said solder resist divided and constructed up to a corner portion of said mounting pad lines so as to feed a sealing resin spreading uniformity when said semiconductor device is set on said mounting pad.

In accordance with the present invention, there is provided a semiconductor device characterized in that;

having a plural of solder resist between a pair of mounting pad line set up nearly parallel to said mounting pad lines each other;

said solder resist divided and constructed up to a corner portion of said mounting pad lines so as to feed a sealing resin spreading uniformity when said semiconductor device is set on said mounting pad.

In accordance with the present invention, there is provided a semiconductor device characterized in that;

having a plural of solder resist between two pairs of mounting pad line set up nearly parallel to said mounting pad lines each other;

said solder resist divided diagonal direction formed by said two pairs of mounting pad line up to a corner portion of said mounting pad line so as to feed (or pour) a sealing resin spreading uniformity when said semiconductor device is set on said mounting pad.

In accordance with the present invention, there is provided a semiconductor device mounting method of mounting a semiconductor device on a substrate by pressure welding in which the method employs one-point coating by a dispenser to mount a semiconductor device on a substrate with high reliability of connection therebetween at a low cost with high productivity.

In accordance with the present invention, there is provided a semiconductor device mounting method. In the method, on a substrate on which a mounting pad including a mounting section is formed, sealing resin is supplied by one-point coating onto a central position of the mounting section, a semiconductor device including a plurality of projected electrodes is placed on the substrate, and the resin is heated under a predetermined pressure to thereby mount the semiconductor device onto the substrate. The method includes the steps of arranging in the mounting section a plurality of solder resist zones to orient a flow of the sealing resin in a predetermined direction, the zones projecting upward; mounting the semiconductor device on the mounting section and supplying thereby the sealing resin in a circumferential area of the semiconductor device mounted on the substrate, and forming with the sealing resin a filet in the circumferential area, the filet being uniform in quantity of resin.

In accordance with the present invention, the semiconductor device mounting method further includes the step of arranging, on an inner side of the mounting pad on the substrate, the solder resist zones each of which has a rectangular contour. The solder resist zones are respectively parallel to edges of the semiconductor device mounted on the substrate.

In accordance with the present invention, the semiconductor device mounting method includes the step of arranging, on an inner side of the mounting pad on the substrate, the solder resist zones each of which has a trapezoidal contour. The trapezoidal contour includes a lower edge on an outer side of the mounting section and an upper edge on a central side of the mounting section, the upper edge being longer than the lower edge. The upper and lower edges are parallel to an associated one of edges of the semiconductor device mounted on the substrate.

In accordance with the present invention, the semiconductor device mounting method further includes the step of arranging, on an inner side of the mounting pad on the substrate, two solder resist zones each of which has a trapezoidal contour, the zones opposing each other. The trapezoidal contour includes a lower edge on an outer side of the mounting section and an upper edge on a central side of the mounting section, the lower edge being longer than the upper edge. The upper and lower edges are parallel to a longer edge of the rectangular contour of the semiconductor device mounted on the substrate. The method further includes the step of arranging, on an inner side of the mounting pad on the substrate, two solder resist zones each of which has a triangular contour, the zones opposing each other. The triangular contour includes a bottom edge on a peripheral side of the mounting section and a vertex opposing the bottom edge on a central side of the mounting section. The bottom edge are parallel to a shorter edge of the semiconductor device mounted on the substrate.

In accordance with the present invention, in one of the semiconductor device mounting methods above, the solder resist zones has a thickness ranging from 10 μm to 30 μm.

In accordance with the present invention, in one of the semiconductor device mounting methods above, the sealing resin is an epoxy-based instantaneous thermosetting resin in which a contraction ratio is larger than an expansion ratio.

### BRIEF DESCRIPTION OF THE DRAWINGS

The objects and features of the present invention will become more apparent from the consideration of the following detailed description taken in conjunction with the accompanying drawings in which:

FIG. 1 is a schematic diagram showing a first example of a solder resist pattern of the prior art;

FIG. 2 is a diagram illustratively showing a second example of a solder resist pattern of the prior art;

FIG. 3 is an illustrative diagram showing a third example of a solder resist pattern of the prior art.

FIG. 4 is a schematic diagram showing a solder resist pattern in a first embodiment in accordance with the present invention, and FIG. 4 (2) shows a cross sectional view of A-A line of FIG. 4 (1);

FIG. 5 is a diagram schematically showing a solder resist pattern in a second embodiment in accordance with the present invention, and FIG. 5 (2) shows a cross sectional view of A-A line of FIG. 5 (1);

FIG. 6 is a schematic diagram showing a solder resist pattern in a third embodiment in accordance with the present invention, and FIG. 6 (2) shows a cross sectional view of A-A line of FIG. 6 (1); and

FIGS. 7A to 7F are diagrams of cross-sectional views showing an embodiment of a process to mount a semiconductor device on a substrate in accordance with the present invention;

### DESCRIPTION OF THE PREFERRED EMBODIMENTS

The present invention characterizes in a plural of solder resist 2 between a pair of mounting pad line(s) constructing mounting pad 3, 3, . . . , set up nearly parallel to said mounting pad line(s) each other;

said solder resist 2 constructing dividedly up to a corner portion of said mounting pad line(s) so as to spread a sealing resin uniformity when said semiconductor device is set on said mounting pad. Using by these substrate, semiconductor device is mounted LSI having a protruding electrodes (bump electrodes) on the substrate and a sealing resin between LSI and substrate is cured, then mounted semiconductor device is produced. It is preferred that a plural of divided solder resist 2 or trenched solder resist 2 on substrate between a pair of mounting pad line(s) constructing mounting pad 3, 3, . . . , set up nearly parallel to said mounting pad line(s) each other;

said solder resist constructing up to a corner portion of said mounting pad lines so as to spread or pouring a sealing resin uniformity when said semiconductor device is set on said mounting pad.

Next, semiconductor device and the semiconductor device mounting method thereof according to the present invention, will be described in accordance of the drawing.

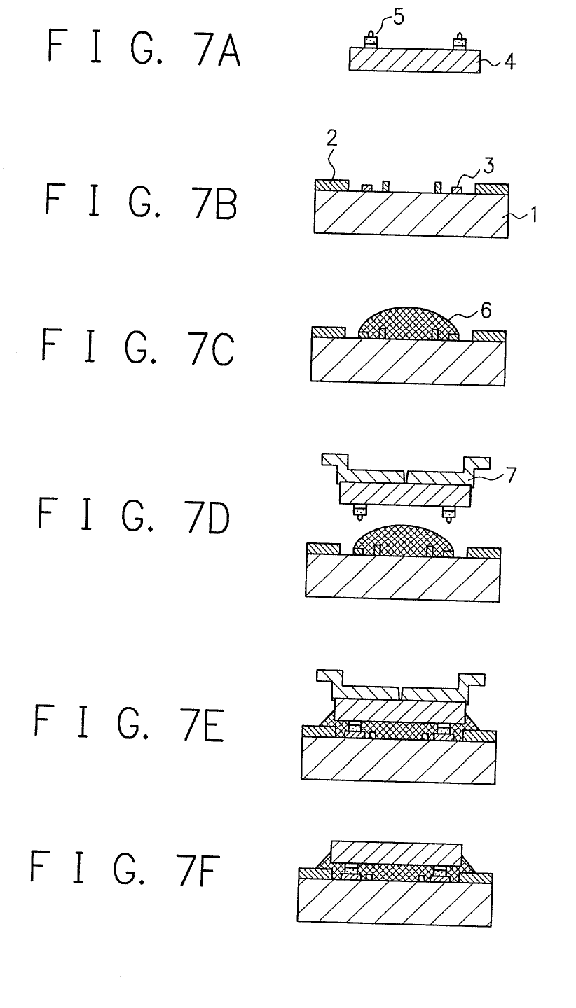

FIGS. 7A to 7F show, in cross-sectional views taken along a mounting pad on a circuit substrate, an embodiment of a flip chip mounting process in accordance with the present invention.

FIG. 7A shows an LSI semiconductor device 4 including bump electrodes 5 thereon. Although material of the electrodes 5 is not limited, it is favorable to employ material which deforms on a mounting pad 3 on a circuit substrate 1 by load imposed on the material when the device 4 is mounted thereon. The embodiment uses gold (Au) as the material. Each bump electrode 5 has favorably a contour of which a tail edge section is pointed.

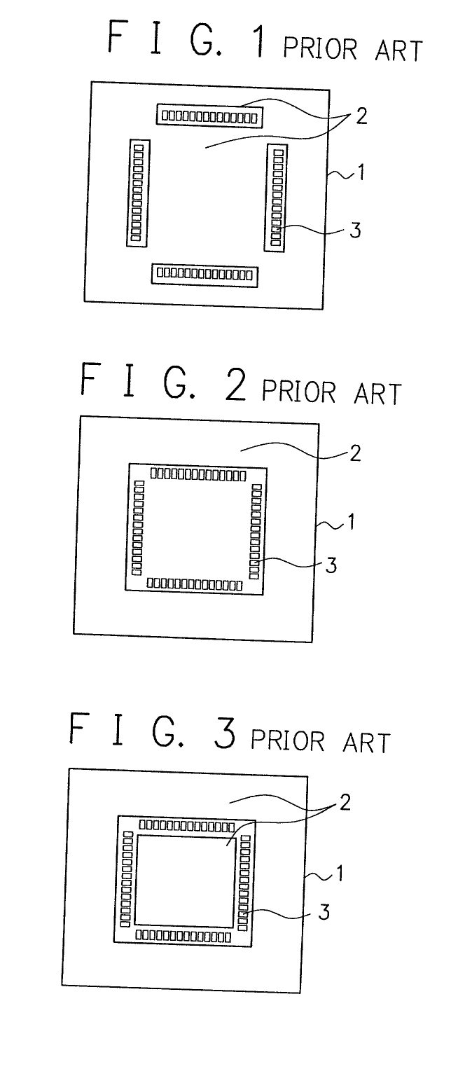

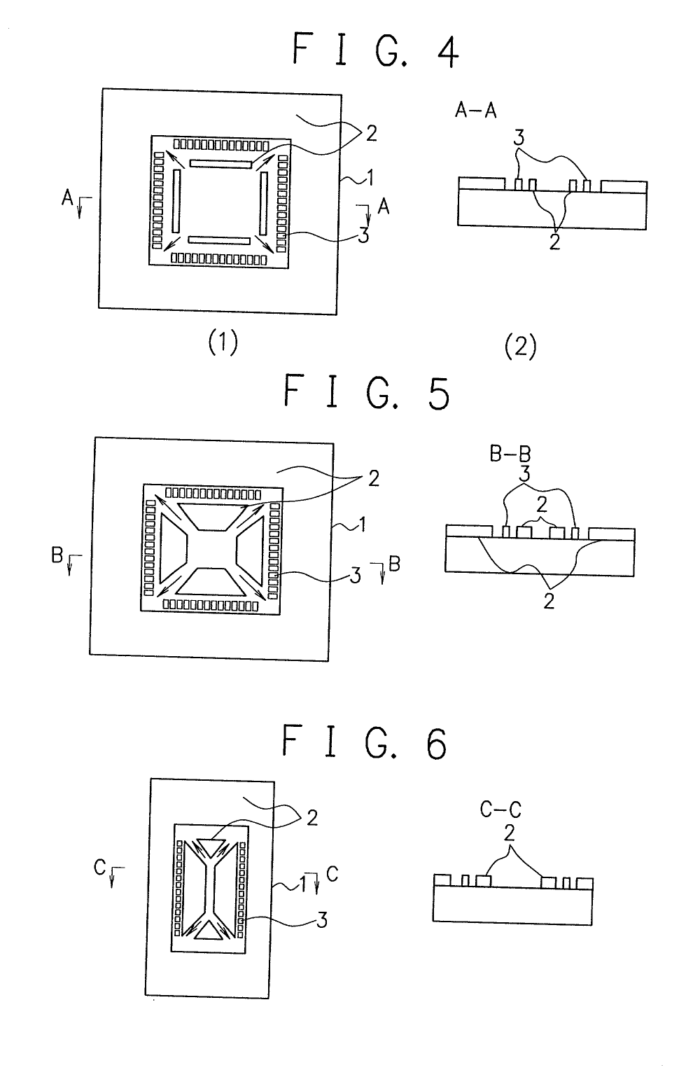

FIG. 7B shows the circuit substrate 1 before the mounting operation. In the embodiment, although the substrate 1 may be made of any appropriate material, the embodiment adopts a printed circuit board fabricated in a build-up method. FIG. 4 shows a solder resist pattern employed in the embodiment. In the embodiment, the solder resist is, although not particularly limited to, light-sensitive liquid resist. As can be seen from FIG. 1, in a mounting area of the device 4, the pattern of the solder resist 2 is formed to prevent a flow of sealing resin 6. The resist 2 favorably has a thickness of 10 micrometers (μm) to 30 μm on the substrate 1 and on the pattern. In this embodiment, the resist 2 is 30 μ m thick on the substrate 1 and 20 μm on the pattern.

As shown in FIG. 7C, the sealing resin 6 is supplied to a central section of the mounting area on the substrate 1. For this purpose, the present invention employs a one-point coating by a known dispenser. The sealing resin 6 is epoxy-based instantaneous thermosetting resin of which a ratio of contraction is larger than a ratio of thermal expansion of cured the sealing resin. The sealing resin 6 is completely set or hardened in about 30 seconds at 200° C. The sealing resin 6 is supplied on the substrate 1 by the one-point coating. The supplied resin 6 is in a contour of about a semispherical shape by surface tension of the resin 6.

Next, the bump electrodes 5 on the device 4 heated to a predetermined temperature are aligned with the mounting pad 3 on the substrate heated to a predetermined temperature as shown in FIG. 7D. Each of the device 4 and the substrate 1 is heated to, not particularly limited to, for example, the range of temperature is from room temperature (about 30° C.) to less than curing temperature, more preferably, from about 55° C. to less than 80 degrees of curing temperature, in the embodiment it was performed this temperature at 80° C.

As can be seen from FIG. 7E, the device 4 is mounted onto the substrate 1 and is heated under a predetermined pressure. Under the pressure, all bump electrodes 5 are brought into contact with the mounting pad 3 and are deformed to a predetermined extent. The pressure is 30 gram (g) per bump electrode 5 in the embodiment. By the pressure, the bump electrode 5 is reduced in height from 100 μm to 60 μ m. The device 4 is heated at 200° C. and the substrate is heated at 80° C. for a period of 30 seconds. In this situation, the sealing resin 6 flows in a direction toward corner areas of the device 4, the direction being oriented by the pattern of the solder resist 2 formed on the substrate 1.

In the method, a filet is formed with a uniform quantity of resin 6 in a circumferential area of the device 4 as shown in FIG. 7F. This results in package structure having high reliability.

In the embodiment, the solder resist 2 is formed in the contour of the pattern shown in FIG. 4. However, the solder resist 2 may be configured in the patterns respectively of FIGS. 5 and 6 as other embodiments in accordance with the present invention. By the solder resist patterns shown in FIGS. 4 to 6, the flow of the resin 6 is oriented toward the corner areas of the device 4 in the mounting process. In these FIGS. 4 (1) to 6(1), arrows show a pouring direction of sealing resin.

The solder resist pattern is formed such that the solder resist 2 surrounds an outer peripheral of the mounting pad 3. In according to the present invention, to orient the flow of the sealing resin 6 toward the corner areas of the device 4 in the mounting operation, the solder resist 2 is arranged in a predetermined layout and with a predetermined contour within the amounting pad 3.

In the embodiments of FIGS. 4 and 5, on an inner edges of the solder resist 2 disposed in a peripheral section of the substrate 1, the mounting pad 3 is formed in parallel with each associated one of the inner edges respectively in four directions. In the embodiment of FIG. 4, on an inner side of each section of the mounting pad 3, a rectangular solder resist 2 is formed in parallel therewith. In the embodiment shown in FIG. 5, on the inner side of each section of the mounting pad 3, a solder resist 2 is formed in a trapezoidal contour. In the trapezoid, an upper edge on the side of a central section of the substrate 1 is shorter than a lower edge on the side of the pad 3 and the upper and lower edges are parallel to the pad 3.

According to the embodiment of FIG. 6, two mounting pads 2 are disposed on the substrate 1 to oppose each other. On an inner side of each pad 2, a trapezoidal solder resist 2 is fabricated. In the contour of the resist 2, a lower edge on the side of the pad 3 is longer than an upper edge on the side of a central section of the substrate 1, and the upper and lower edges are parallel to the pad 3. Moreover, on an inner side of each of the remaining edges which oppose each other, a triangular solder resist 2 is arranged. The triangle includes a bottom edge on a peripheral side of the substrate 1 and a vertex opposing the bottom edge on a central section of the substrate 1.

In the embodiments having the solder resist patterns with thickness described above, the resin being expanded can naturally surmount the resist patterns. However, the flow of the resin is facilitated in different ways between an area with the pattern and an area without the pattern. Using the difference in the easiness of flow between these areas, the resin flow is oriented toward the corner areas of the device 4. Resultantly, almost an equal quantity of resin can be supplied to the central section and to the corner areas of the device 4 in the mounting process.

Description has been given of embodiments suitable for the present invention. However, the present invention is not restricted by these embodiments. Namely, the present invention is applicable to any configuration in which a solder resist having a contour which orients a flow of sealing resin in a predetermined direction is disposed in an LSI semiconductor device mounting section.

In accordance with the present invention described above, in an LSI semiconductor device mounting or packaging process utilizing pressure welding, highly reliable connection can be established between a semiconductor device and a substrate by one-point coating without using any particular, expensive resin supply method and without increasing the mounting process time and the quantity of resin supplied for the following reasons.

In accordance with the present invention, the flow of resin supplied between the LSI semiconductor device and the mounting substrate can be controlled. This resultantly removes the difficulty that the filet in the periphery of a chip is nonuniform in the one-point coating. Namely, the filet can be uniformly configured in accordance with the present invention.

While the present invention has been described with reference to the particular illustrative embodiments, it is not to be restricted by those embodiments but only by the appended claims. It is to be appreciated that those skilled in the art can change or modify the embodiments without departing from the scope and spirit of the present invention.

What is claimed is:

1. A semiconductor device characterized in that;
having a plural of solder resist between a pair of mounting pad line set up nearly parallel to said mounting pad line each other;
said solder resist constructing up to a corner portion of said mounting pad lines so as to spread a sealing resin uniformity when said semiconductor device is set on said mounting pad.

2. A semiconductor device characterized in that;
having a plural of solder resist between a pair of mounting pad line set up nearly parallel to said mounting pad line each other;
said solder resist divided and constructed up to a corner portion of said mounting pad lines so as to feed a sealing resin spreading uniformity when said semiconductor device is set on said mounting pad.

3. A semiconductor device characterized in that;
having a plural of solder resist between a pair of mounting pad line set up nearly parallel to said mounting pad lines each other;
said solder resist divided and constructed up to a corner portion of said mounting pad lines so as to feed a sealing resin spreading uniformity when said semiconductor device is set on said mounting pad.

4. A semiconductor device characterized in that;
having a plural of solder resist between two pairs of mounting pad line set up nearly parallel to said mounting pad lines each other;
said solder resist divided diagonal direction formed by said two pairs of mounting pad line up to a corner portion of said mounting pad line so as to feed a sealing resin spreading uniformity when said semiconductor device is set on said mounting pad.

5. A semiconductor device mounting method in which on a substrate on which a mounting pad including a mounting section is formed, sealing resin is supplied by one-point coating onto a central position of the mounting section, a semiconductor device including a plurality of projected electrodes is placed on the substrate, and the resin is heated under a predetermined pressure to thereby mount the semiconductor device onto the substrate, comprising the steps of:
arranging in the mounting section a plurality of solder resist zones to orient a flow of the sealing resin in a predetermined direction, the zones projecting upward;
mounting the semiconductor device on the mounting section and supplying thereby the sealing resin in a circumferential area of the semiconductor device mounted on the substrate; and
forming with the sealing resin a filet in the circumferential area, the filet being uniform in quantity of resin.

6. The semiconductor device mounting method in accordance with claim 5, wherein the solder resist zones has a thickness ranging from 10 μm to 30 μm.

7. The semiconductor device mounting method in accordance with claim 5, wherein the sealing resin is an epoxy-based instantaneous thermosetting resin having a contraction ratio and an expansion ratio of cured resin, the contraction ratio larger than the expansion ratio.

8. The semiconductor device mounting method in accordance with claim 5, wherein the solder resist zones has a thickness ranging from 10 μm to 30 μm and the sealing resin is an epoxy-based instantaneous thermosetting resin having a contraction ratio and an expansion ratio of cured resin, the contraction ratio larger than the expansion ratio.

9. A semiconductor device mounting method in which on a substrate on which a mounting pad including a mounting section is formed, sealing resin is supplied by one-point coating onto a central position of the mounting section, a semiconductor device including a plurality of projected electrodes is placed on the substrate, and the resin is heated under a predetermined pressure to thereby mount the semiconductor device onto the substrate, comprising the steps of:
arranging in the mounting section a plurality of solder resist zones to orient a flow of the sealing resin in a predetermined direction, the zones projecting upward;
mounting the semiconductor device on the mounting section and supplying thereby the sealing resin in a circumferential area of the semiconductor device mounted on the substrate;
forming with the sealing resin a filet in the circumferential area, the filet being uniform in quantity of resin; and
further comprising the step of arranging, on an inner side of the mounting pad on the substrate, the solder resist zones each of which has a rectangular contour,
the solder resist zones being respectively parallel to edges of the semiconductor device mounted on the substrate.

10. The semiconductor device mounting method in accordance with claim 9, wherein the solder resist zones has a thickness ranging from 10 μm to 30 μm.

11. The semiconductor device mounting method in accordance with claim 9, wherein the sealing resin is an epoxy-based instantaneous thermosetting resin having a contraction ratio and an expansion ratio of cured resin, the contraction ratio larger than the expansion ratio.

12. The semiconductor device mounting method in accordance with claim 9, wherein the solder resist zones has a thickness ranging from 10 μm to 30 μm and the sealing resin is an epoxy-based instantaneous thermosetting resin having a contraction ratio and an expansion ratio of cured resin, the contraction ratio larger than the expansion ratio.

13. A semiconductor device mounting method in which on a substrate on which a mounting pad including a mounting section is formed, sealing resin is supplied by one-point coating onto a central position of the mounting section, a semiconductor device including a plurality of projected electrodes is placed on the substrate, and the resin is heated under a predetermined pressure to thereby mount the semiconductor device onto the substrate, comprising the steps of:
arranging in the mounting section a plurality of solder resist zones to orient a flow of the sealing resin in a predetermined direction, the zones projecting upward;
mounting the semiconductor device on the mounting section and supplying thereby the sealing resin in a circumferential area of the semiconductor device mounted on the substrate;
forming with the sealing resin a filet in the circumferential area, the filet being uniform in quantity of resin; and further comprising the step of arranging, on an inner side of the mounting pad on the substrate, the solder resist zones each of which has a trapezoidal contour,
the trapezoidal contour including a lower edge on an outer side of the mounting section and an upper edge on a central side of the mounting section, the upper edge being longer than the lower edge,
the upper and lower edges being parallel to an associated one of edges of the semiconductor device mounted on the substrate.

14. The semiconductor device mounting method in accordance with claim 13, wherein the solder resist zones has a thickness ranging from 10 μm to 30 μm.

15. The semiconductor device mounting method in accordance with claim 13, wherein the sealing resin is an epoxy-based instantaneous thermosetting resin having a contraction ratio and an expansion ratio of cured resin, the contraction ratio larger than the expansion ratio.

16. The semiconductor device mounting method in accordance with claim 13, wherein the solder resist zones has a thickness ranging from 10 μm to 30 μm and the sealing resin is an epoxy-based instantaneous thermosetting resin having a contraction ratio and an expansion ratio of cured resin, the contraction ratio larger than the expansion ratio.

17. A semiconductor device mounting method in which on a substrate on which a mounting pad including a mounting section is formed, sealing resin is supplied by one-point coating onto a central position of the mounting section, a semiconductor device including a plurality of projected electrodes is placed on the substrate, and the resin is heated under a predetermined pressure to thereby mount the semiconductor device onto the substrate, comprising the steps of:
arranging in the mounting section a plurality of solder resist zones to orient a flow of the sealing resin in a predetermined direction, the zones projecting upward;
mounting the semiconductor device on the mounting section and supplying thereby the sealing resin in a circumferential area of the semiconductor device mounted on the substrate;
forming with the sealing resin a filet in the circumferential area, the filet being uniform in quantity of resin; and further comprising the step of arranging, on an inner side of the mounting pad on the substrate, two solder resist zones each of which has a trapezoidal contour, the zones opposing each other,
the trapezoidal contour including a lower edge on an outer side of the mounting section and an upper edge on a central side of the mounting section, the lower edge being longer than the upper edge,
the upper and lower edges being parallel to a longer edge of the rectangular contour of the semiconductor device mounted on the substrate,
the method further comprising the step of arranging, on an inner side of the mounting pad on the substrate, two solder resist zones each of which has a triangular contour, the zones opposing each other,
the triangular contour including a bottom edge on a peripheral side of the mounting section and a vertex opposing the bottom edge on a central side of the mounting section,
the bottom edge being parallel to a shorter edge of the semiconductor device mounted on the substrate.

18. The semiconductor device mounting method in accordance with claim 17, wherein the solder resist zones has a thickness ranging from 10 μm to 30 μm.

19. The semiconductor device mounting method in accordance with claim 17, wherein the sealing resin is an epoxy-based instantaneous thermosetting resin having a contraction ratio and an expansion ratio of cured resin, the contraction ratio larger than the expansion ratio.

20. The semiconductor device mounting method in accordance with claim 17, wherein the solder resist zones has a thickness ranging from 10 μm to 30 μm and the sealing resin is an epoxy-based instantaneous thermosetting resin having a contraction ratio and an expansion ratio of cured resin, the contraction ratio larger than the expansion ratio.
